(19) United States
(12) Patent Application Publication
(10) Pub. No.: US 2023/0232693 A1
(43) Pub. Date: Jul. 20, 2023

(54) IMAGE DISPLAY DEVICE AND ELECTRONIC DEVICE

(71) Applicant: Sony Semiconductor Solutions Corporation, Kanagawa (JP)

(72) Inventor: Seiichiro Jinta, Kanagawa (JP)

(21) Appl. No.: 18/023,118

(22) PCT Filed: Jul. 15, 2021
(86) PCT No.: PCT/JP2021/026705

§ 371 Date: Feb. 24, 2023

(30) Foreign Application Priority Data
Sep. 3, 2020 (JP) 2020-148540

(51) Int. Cl. H10K 59/80

(52) U.S. Cl. CPC H10K 59/873; H10K 59/12

(57) ABSTRACT

[Problem] Provided is an image display device and an electronic device that can suppress the influence of diffracted light.

[Solution] An image display device includes a plurality of pixels in a two-dimensional array, wherein each of some of the plurality of pixels includes: a first self-emitting device, a first luminous region illuminated by the first self-emitting device, a nonluminous region having a transmissive window that allows passage of visible light, and an optical path adjusting member that is disposed on a light emission side opposed to the light entry side of the transmissive window and adjusts the optical path of light having passed through the transmissive window.

### TECHNICAL FIELD

The present disclosure relates to an image display device and an electronic device.

### BACKGROUND ART

In recent electronic devices such as a smartphone, a cellular phone, and a PC (Personal Computer), various sensors such as a camera are installed on the bezel of a display panel. The number of installed sensors tends to increase. For example, a sensor for face recognition, an infrared sensor, and a moving-object sensor are installed in addition to a camera. In view of the design and the trend toward miniaturization, electronic devices designed with minimum outer dimensions without affecting screen sizes are demanded, and bezel widths tend to decrease. Against this backdrop, a technique is proposed to image subject light, which has passed through a display panel, with an image sensor module disposed immediately under the display panel. In order to dispose the image sensor module immediately under the display panel, the display panel needs to be transparent (see PTL 1).

### CITATION LIST

### Patent Literature

[PTL 1]

JP 2011-175962A

### SUMMARY

### Technical Problem

However, each pixel of the display panel has opaque members such as a pixel circuit and a wiring pattern and further includes an insulating layer having a low transmittance. Thus, the image module disposed immediately under the display panel causes incident light on the display panel from being irregularly reflected, refracted, and diffracted in the display panel, so that the light generated by the reflection, refraction, and diffraction (hereinafter referred to as diffracted light) is caused to enter the image sensor module. Imaging with diffracted light may reduce the image quality of a subject image.

Hence, the present disclosure provides an image display device and an electronic device that can suppress the influence of diffracted light.

### Solution to Problem

In order to solve the problem,

the present disclosure provides an image display device including a plurality of pixels in a two-dimensional array,

wherein each of at least some of the plurality of pixels includes:

a first self-emitting device;

a first luminous region illuminated by the first self-emitting device;

a nonluminous region having a transmissive window that allows passage of visible light; and

an optical path adjusting member that is disposed on a light emission side opposed to the light entry side of the transmissive window and adjusts the optical path of light having passed through the transmissive window.

The optical path adjusting member may adjust the optical path of light having passed through the transmissive window, so that the optical path of light gets closer to the direction of light passing in the direction of the normal of the transmissive window through the center of the transmissive window.

The optical path adjusting member may adjust the optical path of diffracted light of light having passed through the transmissive window.

In plan view from the display surface of the image display device, the nonluminous region may be disposed at a position overlapping a light receiving device for receiving light passing through the image display device.

A pixel circuit connected to the first self-emitting device may be disposed in the first luminous region.

The optical path adjusting member may include a photorefractive member that refracts light having passed through the transmissive window, in the direction of light passing in the direction of the normal of the transmissive window through the center of the transmissive window.

The optical path adjusting member may be disposed on the opposite side of a substrate from the display surface of the substrate on which the plurality of pixels are disposed.

The optical path adjusting member may be a visible-light transmission film that is bonded to the substrate and has the photorefractive member.

The optical path adjusting member may be disposed on the opposite side of a substrate from the display surface of the substrate on which the plurality of pixels are disposed.

The photorefractive member may be a Fresnel lens or a diffractive lens.

The optical path adjusting member may include an optical control member having a higher refractive index than the material of the transmissive window.

The optical control member may contain an addition agent that raises the refractive index of the optical control member higher than the refractive index of the transmissive window.

The optical control member may be disposed in a location where light travels after passing through the transmissive window in a substrate on which the plurality of pixels are disposed.

The image display device may further include: first pixel regions including some of the plurality of pixels; and

second pixel regions including at least some of the plurality of pixels other than the pixels in the first pixel regions,

wherein the pixel in the first pixel region may include the first self-emitting device, the first luminous region, and the nonluminous region, and

the pixel in the second pixel region may include:

a second self-emitting device; and

a second luminous region that is illuminated by the second self-emitting device and has a larger area than the first luminous region.

The first pixel regions may be spaced at a plurality of points in a pixel display region.

In plan view from the display surface of the image display device, the optical path adjusting member may be disposed at least in a location overlapping the first pixel region.

The plurality of transmissive windows may be provided, and

the transmissive windows may be disposed such that light having passed through some of the transmissive windows enters the optical path adjusting member and light having passed through the other transmissive windows does not enter the optical path adjusting member.

The present disclosure provides an electronic device including: an image display device including a plurality of pixels that are two-dimensionally arranged, and a light receiver that receives light passing through the image display device, wherein the image display device has first pixel regions including some of the plurality of pixels,

each of said some of the pixels in the first pixel regions includes:

a first self-emitting device;

a first luminous region illuminated by the first self-emitting device;

a nonluminous region having a transmissive window that allows passage of visible light; and

an optical path adjusting member that is disposed on a light emission side opposed to the light entry side of the transmissive window and adjusts the optical path of light having passed through the transmissive window, and

in plan view from the display surface of the image display device, at least some of the first pixel regions are disposed so as to overlap the light receiver.

The light receiver may receive light through the nonluminous region.

The light receiver may include at least one of an imaging sensor that performs photoelectric conversion on incident light passing through the nonluminous region, a distance measuring sensor that receives incident light passing through the nonluminous region and measures a distance, and a temperature sensor that measures a temperature on the basis of incident light passing through the nonluminous region.

### BRIEF DESCRIPTION OF DRAWINGS

FIG. 1 shows a broken line indicating an example of a specific location of a sensor disposed immediately under a display panel.

FIG. 2A illustrates an example in which the two sensors are disposed on the backside of the display panel and are located on the upper side with respect to the center of the display panel.

FIG. 2B illustrates an example in which the sensors 5 are disposed at the four corners of the display panel.

FIG. 3 is a schematic diagram illustrating the structure of a pixel in a first pixel region and the structure of a pixel in a second pixel region.

FIG. 4 is a cross-sectional view illustrating an image sensor module.

FIG. 5 is an explanatory drawing schematically illustrating the optical configuration of the image sensor module.

FIG. 6 is an explanatory drawing illustrating an optical path where light from a subject forms an image on an image sensor.

FIG. 7 is a circuit diagram of the basic configuration of a pixel circuit including an OLED.

FIG. 8 is a plan layout of the pixels in the second pixel regions.

FIG. 9 is a cross-sectional view of the pixel in the second pixel region that is not disposed directly above the sensor.

FIG. 10 is a cross-sectional view illustrating an example of the laminated structure of a display layer.

FIG. 11 is a plan layout of the pixels in the first pixel regions that are disposed directly above the sensor.

FIG. 12 is a cross-sectional view of the pixel in the first pixel region that is disposed directly above the sensor.

FIG. 13 is an explanatory drawing of a diffraction phenomenon that generates diffracted light.

FIG. 14 is a cross-sectional view illustrating a comparative example of the optical path of diffracted light.

FIG. 15 is a cross-sectional view illustrating a first example of the configuration of the optical path adjusting member.

FIG. 16 is a cross-sectional view illustrating a second example of the configuration of the optical path adjusting member.

FIG. 17 is a cross-sectional view illustrating a third example of the configuration of the optical path adjusting member.

FIG. 18 illustrates a first modification example of a microlens.

FIG. 19 illustrates a second modification example of the microlens.

FIG. 20 illustrates a first example of suppression of image degradation.

FIG. 21 illustrates a second example of suppression of image degradation.

FIG. 22 is a cross-sectional view illustrating a first modification example of the cross-sectional structure of the first pixel region.

FIG. 23 is a cross-sectional view illustrating a second modification example of the cross-sectional structure of the first pixel region.

FIG. 24 is a cross-sectional view illustrating a third modification example of the cross-sectional structure of the first pixel region.

FIG. 25 is a cross-sectional view illustrating a fourth modification example of the cross-sectional structure of the first pixel region.

FIG. 26 is a cross-sectional view illustrating a fifth modification example of the cross-sectional structure of the first pixel region.

FIG. 27 is a cross-sectional view illustrating a sixth modification example of the cross-sectional structure of the first pixel region.

FIG. 28 is a cross-sectional view illustrating a seventh modification example of the cross-sectional structure of the first pixel region.

FIG. 29 is a cross-sectional view illustrating an eighth modification example of the cross-sectional structure of the first pixel region.

FIG. 30 is a plan view of an electronic device applied to a capsule endoscope according to the first embodiment.

FIG. 31 is a rear view of the electronic device applied to a digital single-lens reflex camera according to the first embodiment.

FIG. 32A is a plan view illustrating the electronic device applied to an HMD according to the first embodiment.

FIG. 32B illustrates an existing HMD.

### DESCRIPTION OF EMBODIMENTS

Embodiments of an image display device and an electronic device will be described below with reference to the drawings. Hereinafter, the main components of the image display device and the electronic device will be mainly described. The image display device and the electronic device may include components and functions that are not illustrated or explained. The following description does not exclude components or functions that are not illustrated or described.

### First Embodiment

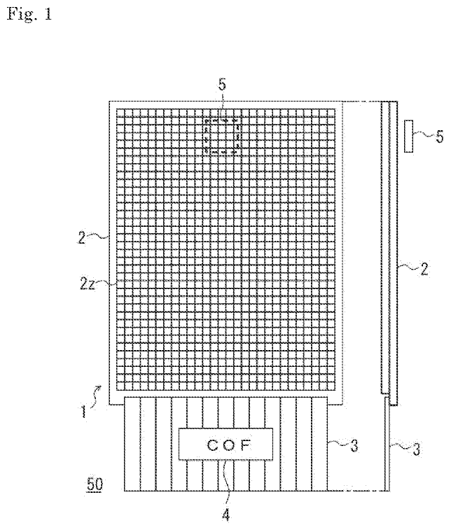

FIG. 1 illustrates a plan view and a cross-sectional view of an electronic device 50 including an image display device 1 according to a first embodiment of the present disclosure. As illustrated in FIG. 1, the image display device 1 according to the present embodiment includes a display panel 2. To the display panel 2, for example, flexible printed wiring boards (FPC: Flexible Printed Circuits) 3 are connected. The display panel 2 has a plurality of layers stacked on, for example, a glass substrate or a transparent film and a matrix of pixels on a display surface 2z. On the FPCs 3, a chip (COF: Chip On Film) 4 including at least a part of the driving circuit of the display panel 2 is mounted. The driving circuit may be stacked as a COG (Chip On Glass) on the display panel 2.

The image display device 1 according to the present embodiment is configured such that various sensors 5 for receiving light through the display panel 2 can be disposed immediately under the display panel 2. In the present specification, a configuration including the image display device 1 and the sensors 5 will be referred to as the electronic device 50. The kinds of sensors 5 provided in the electronic device 50 are not particularly specified. For example, the sensor 5 may be an imaging sensor that performs photoelectric conversion on incident light passing through the display panel 2, a distance measuring sensor that projects light through the display panel 2, receives light, which is reflected by an object, through the display panel 2, and measures a distance to the object, or a temperature sensor that measures a temperature on the basis of incident light passing through the display panel 2. As described above, the sensor 5 disposed immediately under the display panel 2 has at least the function of a light receiver for receiving light. The sensor 5 may have the function of a light emitter for projecting light through the display panel 2.

FIG. 1 shows a broken line indicating an example of a specific location of the sensor 5 disposed immediately under the display panel 2. As illustrated in FIG. 1, for example, the sensor 5 is disposed on the backside of the display panel 2 and is located on the upper side of the display panel 2 with respect to the center of the display panel 2. The location of the sensor 5 in FIG. 1 is merely exemplary. The sensor 5 may be disposed at any location. As illustrated in FIG. 1, the sensor 5 is disposed on the backside of the display panel 2. This can eliminate the need for disposing the sensor 5 on the side of the display panel 2, minimize the size of the bezel of the electronic device 50, and place the display panel 2 substantially over the front side of the electronic device 50.

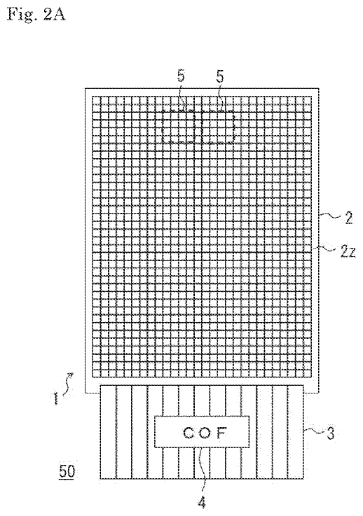

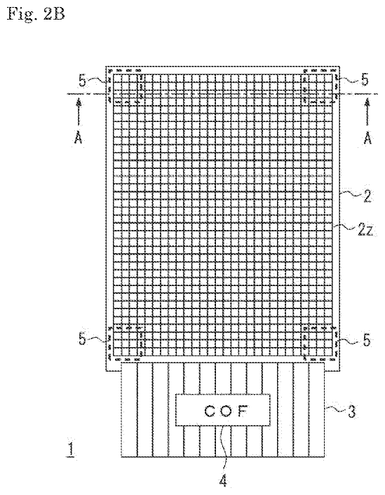

FIG. 1 illustrates an example in which the sensor 5 is disposed at one location of the display panel 2. As illustrated in FIGS. 2A or 2B, the sensors 5 may be disposed at multiple locations. FIG. 2A illustrates an example in which the two sensors 5 are disposed on the backside of the display panel 2 and are located on the upper side with respect to the center of the display panel 2. FIG. 2B illustrates an example in which the sensors 5 are disposed at the four corners of the display panel 2. The sensors 5 are disposed at the four corners of the display panel 2 as illustrated in FIG. 2B for the following reason: A pixel region overlapping the sensors 5 in the display panel 2 is designed with an increased transmittance and thus may have display quality slightly different from that of a surrounding pixel region. A human staring at the center of the screen can closely recognize the center of screen and notice a small difference. However, detail visibility decreases in an outer region serving as a peripheral visual field. Since the center of the screen is frequently viewed in a typical display image, the sensors 5 are recommended to be located at the four corners to make the difference less noticeable.

As illustrated in FIGS. 2A and 2B, when the plurality of sensors 5 disposed on the backside of the display panel 2, the plurality of sensors 5 may be of the same type or different types. For example, a plurality of image sensor modules 9 having different focal lengths may be disposed or the sensors 5 of different types, for example, an imaging sensor 5 and a ToF (Time of Flight) sensor 5 may be disposed.

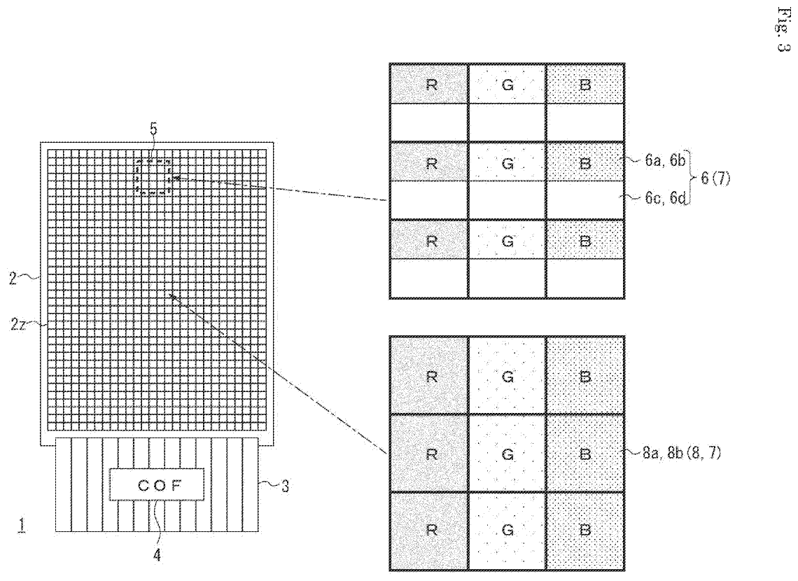

In the present embodiment, a pixel region (first pixel region) overlapping the sensor 5 on the backside and a pixel region (second pixel region) not overlapping the sensor 5 have different pixel structures. FIG. 3 is a schematic diagram illustrating the structure of a pixel 7 in a first pixel region 6 and the structure of the pixel 7 in a second pixel region 8. The pixel 7 in the first pixel region 6 includes a first self-emitting device 6a, a first luminous region 6b, and a nonluminous region 6c. The first luminous region 6b is a region illuminated by the first self-emitting device 6a. The nonluminous region 6c is not irradiated by the first self-emitting device 6a but has a transmissive window 6d in a predetermined shape that allows the passage of visible light. The pixel 7 in the second pixel region 8 includes a second self-emitting device 8a and a second luminous region 8b. The second luminous region 8b is irradiated by the second self-emitting device 8a and has a larger area than the first luminous region 6b.

A representative example of the first self-emitting device 6a and the second self-emitting device 8a is an organic EL (Electroluminescence) device (hereinafter also referred to as an OLED: Organic Light Emitting Diode). At least a part of the self-emitting device can be made transparent because the backlight can be omitted. The use of an OLED as an example of the self-emitting device will be mainly described below.

Instead of the different structures of the pixels 7 in the pixel region overlapping the sensor 5 and the pixel region not overlapping the sensor 5, the same structure may be provided for all the pixels 7 in the display panel 2. In this case, each of the pixels 7 preferably includes the first luminous region 6b and the nonluminous region 6c of FIG. 3 such that the sensor 5 can be disposed at any location in the display panel 2.

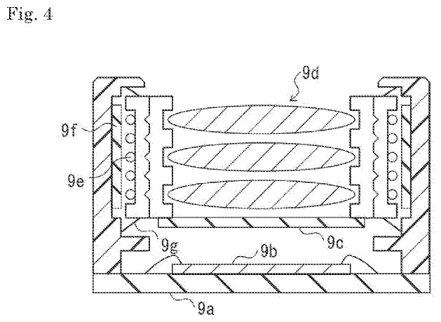

FIG. 4 is a cross-sectional view illustrating the image sensor module 9. As illustrated in FIG. 4, the image sensor module 9 includes an image sensor 9b mounted on a support substrate 9a, an IR (Infrared Ray) cutoff filter 9c, a lens unit 9d, a coil 9e, a magnet 9f, and a spring 9g. The lens unit 9d includes one or more lenses. The lens unit 9d can move along the optical axis according to the direction of current passing through the coil 9d. The internal configuration of the image sensor module 9 is not limited to that illustrated in FIG. 4.

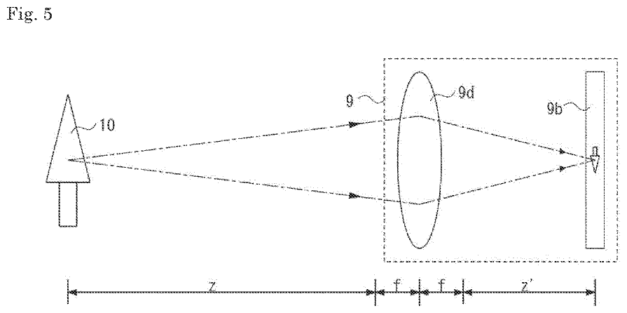

FIG. 5 is an explanatory drawing schematically illustrating the optical configuration of the image sensor module 9. Light from a subject 10 is refracted through the lens unit 9d and forms an image on the image sensor 9b. The larger the amount of incident light passing through the lens unit 9d, the larger the amount of light received by the image sensor 9b, leading to higher sensitivity. In the present embodiment, the display panel 2 is disposed between the subject 10 and the lens unit 9d. It is significant to suppress absorption, reflection, and diffraction on the display panel 2 when light from the subject 10 passes through the display panel 2.

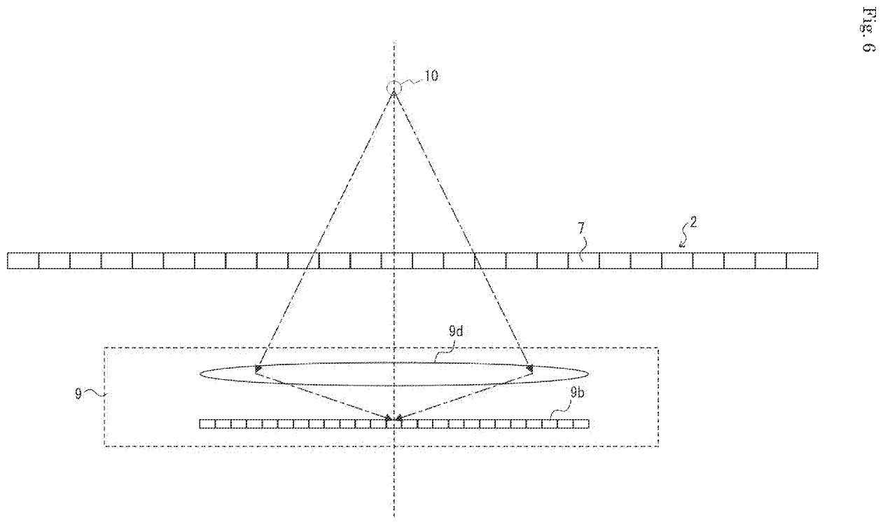

FIG. 6 is an explanatory drawing illustrating an optical path where light from the subject 10 forms an image on the image sensor 9b. In FIG. 6, the pixels 7 of the display panel 2 and the pixels 7 of the image sensor 9b are schematically illustrated as squares. As illustrated in FIG. 6, the pixels 7 of the display panel 2 are considerably larger than the pixels 7 of the image sensor 9b. Light from a specific position of the subject 10 passes through the transmissive window 6d of the display panel 2, is refracted through the lens unit 9d of the image sensor module 9, and forms an image at the specific pixel 7 on the image sensor 9b. In this way, light from the subject 10 passes through the transmissive windows 6d provided for the pixels 7 in the first pixel region 6 of the display panel 2 and enters the image sensor module 9.

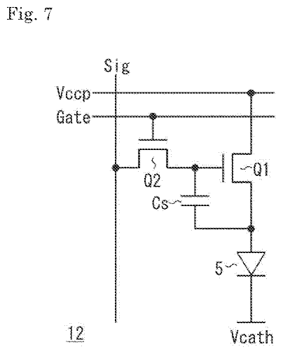

FIG. 7 is a circuit diagram of the basic configuration of a pixel circuit 12 including an OLED 5. The pixel circuit 12 of FIG. 7 includes a drive transistor Q1, a sampling transistor Q2, and a pixel capacitor Cs in addition to the OLED 5. The sampling transistor Q2 is connected between a signal line Sig and the gate of the drive transistor Q1. A scanning line Gate is connected to the gate of the sampling transistor Q2. The pixel capacitor Cs is connected between the gate of the drive transistor Q1 and the anode electrode of the OLED 5. The drive transistor Q1 is connected between a power-supply voltage node Vccp and the anode of the OLED 5.

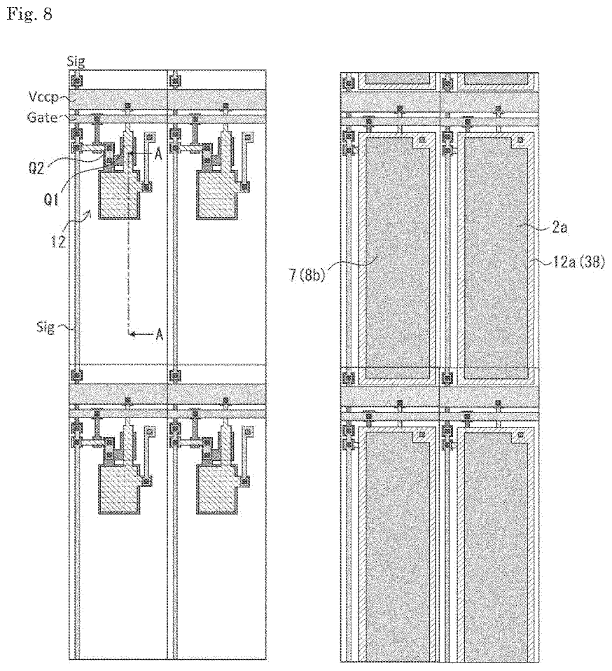

FIG. 8 is a plan layout of the pixels 7 in the second pixel region 8 that is not disposed directly above the sensors 5. The pixels 7 in the second pixel region 8 have typical pixel configurations. The pixels 7 each include multiple color pixels 7 (e.g., the three color pixels 7 of RGB). FIG. 8 illustrates the plan layout of the four color pixels 7: the two horizontal color pixels 7 and the two vertical color pixels 7. Each of the color pixels 7 includes the second luminous region 8b. The second luminous region 8b extends substantially over the color pixel 7. In the second luminous region 8b, the pixel circuit 12 including the second self-emitting device 8a (OLED 5) is disposed. Two columns on the left side of FIG. 8 illustrate a plan layout under anode electrodes 12a, whereas two columns on the right side of FIG. 8 illustrate the plan layout of the anode electrodes 12a and display layers 2a disposed on the anode electrodes 12a.

As illustrated in the two columns on the right side of FIG. 8, the anode electrode 12a and the display layer 2a are disposed substantially over the color pixel 7. The entire region of the color pixel 7 serves as the second luminous region 8b.

As illustrate in the two columns on the left side of FIG. 8, the pixel circuit 12 of the color pixel 7 is disposed in the upper half region of the color pixel 7. On the upper end of the color pixel 7, a wiring pattern for a power-supply voltage Vccp and a wiring pattern for a scanning line are disposed in a horizontal direction X. Furthermore, a wiring pattern for the signal line Sig is disposed along the border of a vertical direction Y of the color pixel 7.

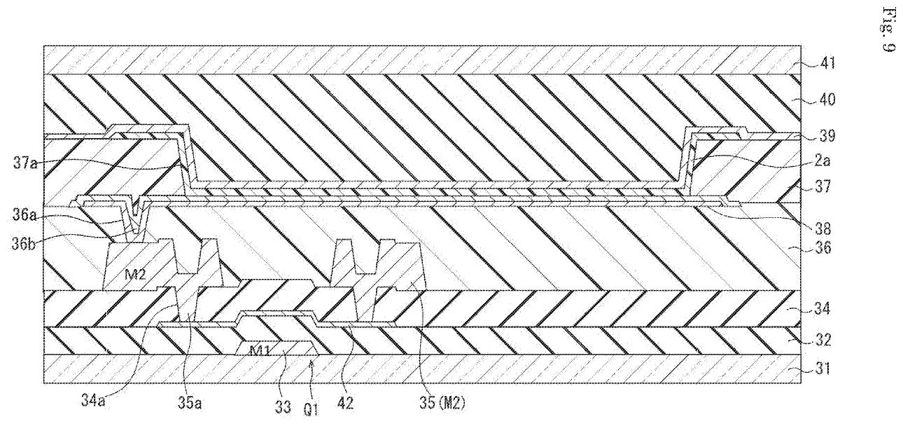

FIG. 9 is a cross-sectional view of the pixel 7 (color pixel 7) in the second pixel region 8 that is not disposed directly above the sensor 5. FIG. 9 illustrates a cross-sectional structure taken along line A-A of FIG. 8. More specifically, FIG. 9 illustrates a cross-sectional structure around the drive transistor Q1 in the pixel circuit 12. Cross-sectional views including FIG. 9 in the accompanying drawings of the present specification emphasize the characteristic layer configurations, and thus the length-to-width ratios do not always agree with the plan layout.

The top surface of FIG. 9 is the display-surface side of the display panel 2, and the bottom of FIG. 9 is a side where the sensor 5 is disposed. From the bottom side to the top-surface side (light emission side) of FIG. 9, a first transparent substrate 31, a first insulating layer 32, a first wiring layer (gate electrode) 33, a second insulating layer 34, a second wiring layer (source wiring or drain wiring) 35, a third insulating layer 36, an anode electrode layer 38, a fourth insulating layer 37, the display layer 2a, a cathode electrode layer 39, a fifth insulating layer 40, and a second transparent substrate 41 are sequentially stacked.

The first transparent substrate 31 and the second transparent substrate 41 are desirably composed of, for example, quartz glass or a transparent film with high transmission of visible light. Alternatively, one of the first transparent substrate 31 and the second transparent substrate 41 may be composed of quartz glass and the other may be composed of a transparent film. In view of manufacturing, a colored and less transmissive film, e.g., a polyimide film may be used. Alternatively, at least one of the first transparent substrate 31 and the second transparent substrate 41 may be composed of a transparent film. On the first transparent substrate 31, a first wiring layer (M1) 33 is disposed to connect the circuit elements in the pixel circuit 12.

On the first transparent substrate 31, the first insulating layer 32 is disposed over the first wiring layer 33. The first insulating layer 32 is, for example, a laminated structure of a silicon nitride layer and a silicon oxide layer with high transmittance of visible light. On the first insulating layer 32, a semiconductor layer 42 is disposed with a channel region formed for the transistors in the pixel circuit 12. FIG. 9 schematically illustrates a cross-sectional structure of the drive transistor Q1 including the gate formed in the first wiring layer 33, the source and drain formed in the second wiring layer 35, and the channel region formed in the semiconductor layer 42. The other transistors are also disposed in the layers 33, 35, and 42 and are connected to the first wiring layer 33 via contacts, which are not illustrated.

On the first insulating layer 32, the second insulating layer 34 is disposed over the transistors or the like. The second insulating layer 34 is, for example, a laminated structure of a silicon oxide layer, a silicon nitride layer, and a silicon oxide layer with high transmission of visible light. In a part of the second insulating layer 34, a trench 34a is formed and is filled with a contact member 35a, so that a second wiring layer (M2) 35 connected to the sources and drains of the transistors is formed in the trench 34a. FIG. 9 illustrates the second wiring layer 35 connecting the drive transistor Q1 and the anode electrode 12a of the OLED 5. The second wiring layer 35 connected to the other circuit elements is also disposed in the same layer. As will be described later, a third wiring layer, which is not illustrated, may be provided between the second wiring layer 35 and the anode electrode 12a in FIG. 9. The third wiring layer may be used for connection to the anode electrode 12a as well as wiring in the pixel circuit.

On the second insulating layer 34, the third insulating layer 36 for covering the second wiring layer 35 to form a flat surface is disposed. The third insulating layer 36 is made of a resin material, e.g., acrylic resin. The third insulating layer 36 has a larger thickness than the first and second insulating layers 32 and 34.

On a part of the top surface of the third insulating layer 36, a trench 36a is formed and is filled with a contact member 36b therein to make an electrical connection to the second wiring layer 35. The contact member 36b is extended to the top surface of the third insulating layer 36 and forms the anode electrode layer 38. The anode electrode layer 38 has a laminated structure including a metallic material layer. The metallic material layer typically has a low transmittance of visible light and acts as a reflective layer that reflects light. A specific metallic material may be, for example, AlNd or Ag.

The bottom layer of the anode electrode layer 38 is in contact with the trench 36a and is prone to break. Thus, in some cases, at least the corners of the trench 36a are made of a metallic material, e.g., AlNd. The top layer of the anode electrode layer 38 includes a transparent conductive layer made of ITO (Indium Tin Oxide) or the like. Alternatively, the anode electrode layer 38 may have a laminated structure of, for example, ITO/Ag/ITO. Ag is originally opaque but the transmittance of visible light is increased by reducing the film thickness. Since Ag with a small thickness leads to lower strength, the laminated structure with ITO on both sides can act as a transparent conductive layer.

On the third insulating layer 36, the fourth insulating layer 37 is disposed over the anode electrode layer 38. The fourth insulating layer 37 is also made of a resin material, e.g., acrylic resin like the third insulating layer 36. The fourth insulating layer 37 is patterned according to the location of the OLED 5 and has a recessed portion 37a.

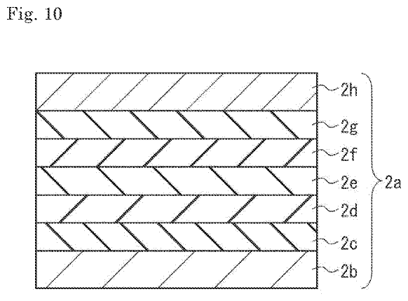

The display layer 2a is disposed so as to include the bottom and the sides of the recessed portion 37a of the fourth insulating layer 37. For example, the display layer 2a has a laminated structure illustrated in FIG. 10. The display layer 2a in FIG. 10 is a laminated structure in which an anode 2b, a hole injection layer 2c, a hole transport layer 2d, a luminescent layer 2e, an electron transport layer 2f, an electron injection layer 2g, and a cathode 2h are disposed in the order of stacking from the anode electrode layer 38. The anode 2b is also called the anode electrode 12a. The hole injection layer 2c is a layer to which a hole is injected from the anode electrode 12a. The hole transport layer 2d is a layer that efficiently transports a hole to the luminescent layer 2e. The luminescent layer 2e recombines a hole and an electron to generate an exciton and emits light when the exciton returns to a ground state. The cathode 2h is also called a cathode electrode. The electron injection layer 2g is a layer to which an electron is injected from the cathode 2h. The electron transport layer 2f is a layer that efficiently transports an electron to the luminescent layer 2e. The luminescent layer 2e contains an organic substance.

The cathode electrode layer 39 is disposed on the display layer 2a illustrated in FIG. 9. The cathode electrode layer 39 includes a transparent conductive layer like the anode electrode layer 38. The transparent conductive layer of the anode electrode layer 38 is made of, for example, ITO/Ag/ITO, whereas the transparent electrode layer of the cathode electrode layer 39 is made of, for example, MgAg.

The fifth insulating layer 40 is disposed on the cathode electrode layer 39. The fifth insulating layer 40 has a flat top surface and is made of an insulating material having high moisture resistance. On the fifth insulating layer 40, the second transparent substrate 41 is disposed.

As illustrated in FIGS. 8 and 9, in the second pixel region 8, the anode electrode layer 38 acting as a reflective film is disposed substantially over the color pixel 7, thereby preventing the passage of visible light.

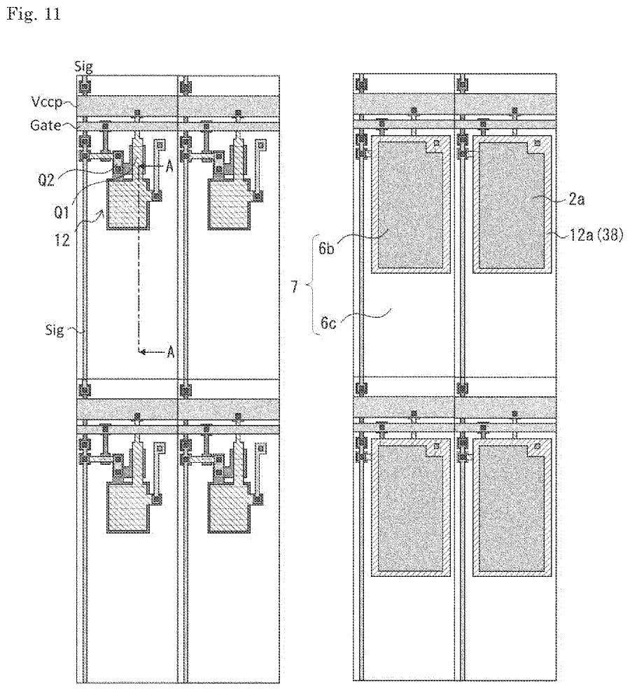

FIG. 11 is a plan layout of the pixels 7 in the first pixel regions 6 that is disposed directly above the sensors 5. The pixels 7 each include multiple color pixels 7 (e.g., the three color pixels 7 of RGB). FIG. 11 illustrates the plan layout of the four color pixels 7: the two horizontal color pixels 7 and the two vertical color pixels 7. Each of the color pixels 7 includes the first luminous region 6b and the nonluminous region 6c. The first luminous region 6b is a region that includes the pixel circuit 12 having the first self-emitting device 6a (OLED 5) and is illuminated by the OLED 5. The nonluminous region 6c is a region that passes visible light.

The nonluminous region 6c cannot emit light from the OLED 5 but can pass incident visible light. Thus, the sensor 5 disposed immediately under the nonluminous region 6c can receive visible light.

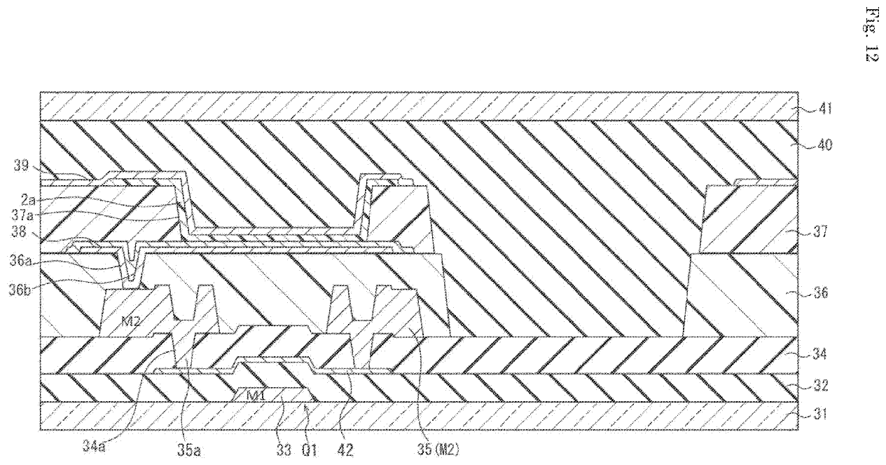

FIG. 12 is a cross-sectional view of the pixel 7 in the first pixel region 6 that is disposed directly above the sensor 5. FIG. 12 illustrates a cross-sectional structure taken along line A-A of FIG. 11, from the first luminous region 6b to the nonluminous region 6c. In comparison with FIG. 9, the third insulating layer 36, the fourth insulating layer 37, the anode electrode layer 38, the display layer 2a, and the cathode electrode 39 are removed in the nonluminous region 6c. Thus, light entering the nonluminous region 6c from above (display surface) in FIG. 12 is emitted from the bottom (backside) and enters the sensor 5 without being absorbed or reflected in the nonluminous region 6c.

However, incident light in the first pixel region 6 is passed through the first luminous region 6b in addition to the nonluminous region 6c and is diffracted therein, causing diffracted light.

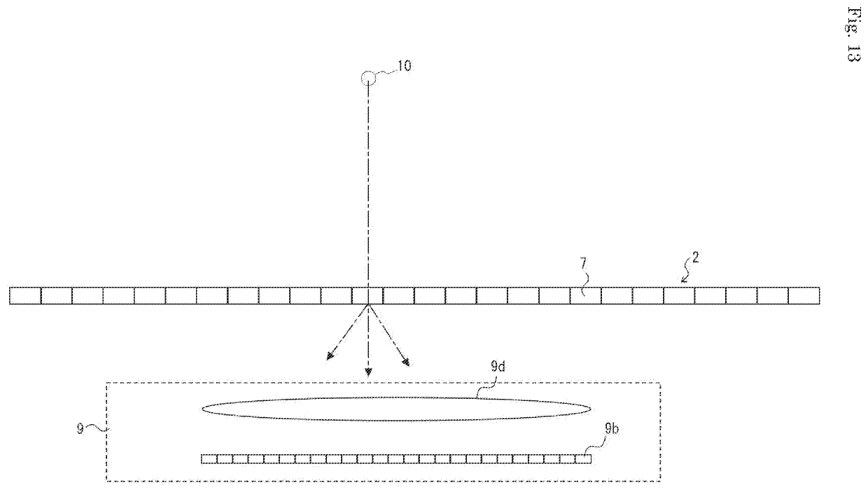

FIG. 13 is an explanatory drawing of a diffraction phenomenon that generates diffracted light. Parallel rays such as sunlight and light having high directivity are diffracted at, for example, a boundary portion between the nonluminous region 6c and the first luminous region 6b and generate high-order diffracted light such as primary diffracted light. Zeroth-order diffracted light is light passing along the optical axis of incident light and has the highest intensity among diffracted light. In other words, zeroth-order diffracted light is an object to be imaged, that is, light to be imaged. Diffracted light of a higher order passes in a direction apart from zeroth-order diffracted light and decreases in light intensity. Generally, high-order diffracted light including primary diffracted light is collectively called diffracted light. Diffracted light is light that is not supposed to be present in subject light and is unnecessary for imaging the subject 10.

In a captured image including diffracted light, the brightest point is zeroth-order light. High-order diffracted light extends in the shape of a cross from zeroth-order diffracted light. When subject light is white light, diffraction angles vary among wavelength components included in the white light, so that rainbow-colored diffracted light f is generated.

The diffracted light fin the shape of a cross will be described as an example. However, the diffracted light f is not always cross-shaped and may be shaped like, for example, a concentric circle.

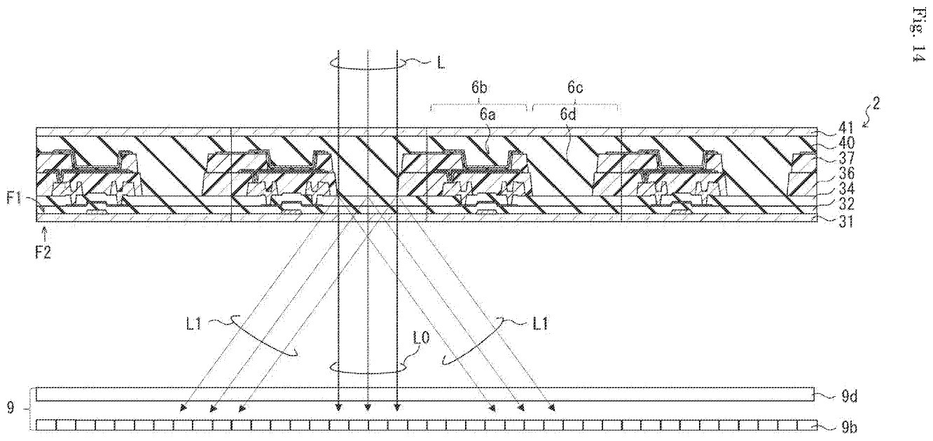

FIG. 14 is a cross-sectional view illustrating a comparative example of the optical path of diffracted light. FIG. 14 corresponds to FIG. 13. Specifically, FIG. 14 illustrates the pixel 7 in the first pixel region 6 that is disposed directly above the sensor 5. FIG. 14 illustrates the image sensor module 9 as the sensor 5.

If the first and second transparent substrates 31 and 41 and the first and second insulating layers 32 and 34 are composed of silicon oxide layers, the first and second transparent substrates 31 and 41 and the first and second insulating layers 32 and 34 have a refractive index of, for example, about 1.45. If the third and fourth insulating layers 36 and 37 are composed of colored resin layers, the third and fourth insulating layers 36 and 37 have a refractive index of, for example, about 1.6. If the fifth insulating layer 40 is made of acrylic resin, the fifth insulating layer 40 has a refractive index of, for example, about 1.49.

In the example of FIG. 14, light L incident on the first pixel region 6 enters the second insulating layer 34 and is diffracted therein. The position of diffraction is merely exemplary and is not limited to the example of FIG. 14. The diffraction allows the emission of zeroth-order diffracted light LO and primary diffracted light L1 from the first pixel region 6. The entry of the zeroth-order diffracted light L0 onto the image sensor module 9 generates an optical spot of the zeroth-order diffracted light at the central position of the overall diffracted light. FIG. 14 illustrates the primary diffracted light L1. Outside the primary diffracted light L1, diffracted light of a second or higher order is generated. The entry of diffracted light of a higher order than the primary diffracted light L1 onto the image sensor module 9 generates diffracted light f other than an optical spot from the overall diffracted light.

In the present embodiment, the influence of the diffracted light f is suppressed by controlling the optical path of diffracted light of a higher order than the primary diffracted light L1. Thus, the image display device 1 further includes an optical path adjusting member 70.

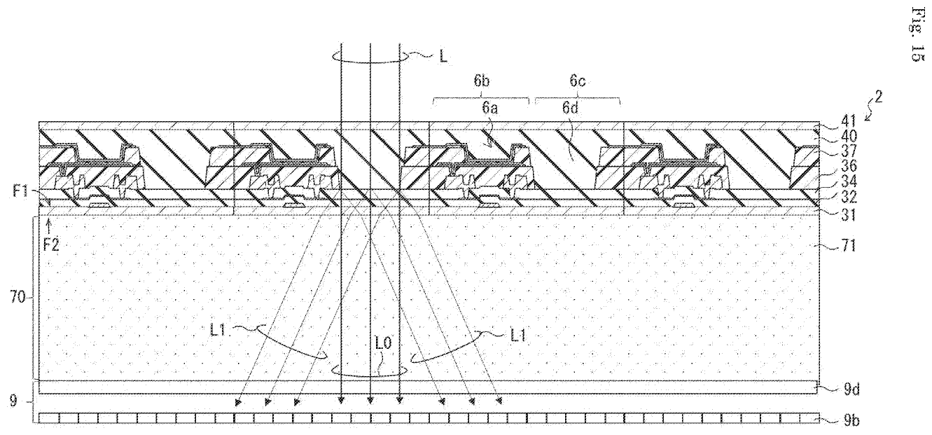

FIG. 15 is a cross-sectional view illustrating a first example of the configuration of the optical path adjusting member 70.

The optical path adjusting member 70 is disposed on the light emission side opposed to the light entry side of the transmissive window 6d and adjusts the optical path of light having passed through the transmissive window 6d. More specifically, the optical path adjusting member 70 adjusts the optical path of light having passed through the transmissive window 6d, close to the direction of light passing in the direction of the normal of the transmissive window 6d through the center of the transmissive window 6d. Furthermore, more specifically, the optical path adjusting member 70 adjusts the optical path of diffracted light of light having passed through the transmissive window 6d. Thus, as illustrated in FIG. 15, the diffraction angle of the primary diffracted light L1 that causes the diffracted light f can be smaller than that in the example of FIG. 14. In other words, the extension of the primary diffracted light L1 can be suppressed. This can reduce the area (size) of the diffracted light f, thereby suppressing the influence of the diffracted light f.

The optical path adjusting member 70 includes an optical control member 71 having a higher refractive index than the material of the transmissive window 6d. In other words, the optical control member 71 bends the optical path by using a difference in refractive index. The optical control member 71 contains an addition agent that raises the refractive index of the optical control member 71 higher than that of the transmissive window 6d. The optical control member 71 is fabricated by adding an additive that increases a refractive index to, for example, polyene-polythiol resin or acrylic resin. In this case, the refractive index of the optical control member 71 is, for example, 2.0. The refractive index of the optical control member 71 may be adjusted according to, for example, the amount and kind of additive. For example, according to the Snell's law, the refractive index is adjusted to obtain a desired angle of refraction. The optical control member 71 may be, for example, a silicon nitride layer having a refractive index of 1.9. The optical control member 71 is, for example, a film like a coating. Moreover, the optical control member 71 preferably has a high transmittance. In this case, for example, a captured image in the image sensor module 9 can be illuminated.

The optical control member 71 is disposed on a second surface F2 of the first transparent substrate 31 having a first surface F1 on which the first self-emitting device 6a is provided and the second surface F2 on the opposite side of the first transparent substrate 31 from the first surface F1. In other words, the optical control member 71 is externally attached to the display panel 2. More specifically, the optical control member 71 is disposed in a location where light travels after passing through the transmissive window 6d in the first transparent substrate 31, on which the pixels 7 are disposed. Moreover, the optical control member 71 is disposed to fill a space between the light emission side of the transmissive window 6d and the sensor 5 (image sensor module 9) that receives light passing through the image display device 1. In other words, the optical control member 71 having a high refractive index is used for bonding the display panel 2 and the sensor 5. A distance between the display panel 2 and the lens unit 9d is preferably minimized. This can shorten the optical path length of the primary diffracted light L1, thereby suppressing the expansion of the primary diffracted light L1.

In the use of the optical control member 71, the refractive index is improved by an addition agent. Thus, the bending angle of the optical path may be limited depending upon a restriction on the material. In this case, a method of bending the optical path by using optical elements such as a lens may be used.

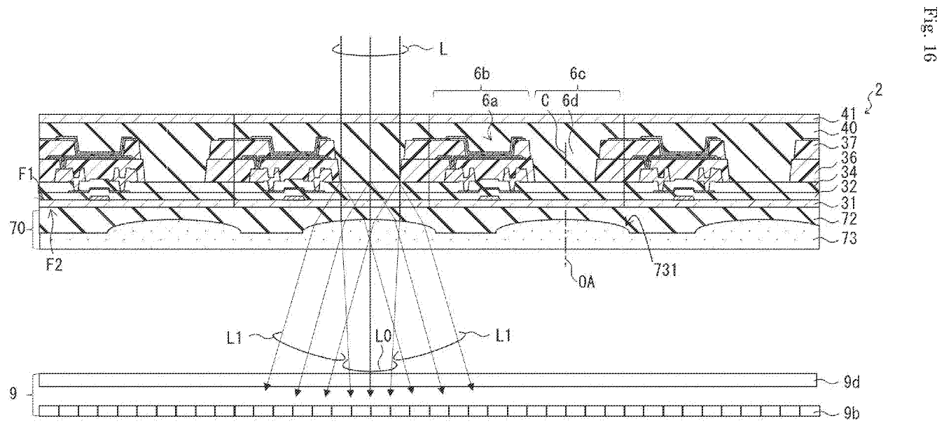

FIG. 16 is a cross-sectional view illustrating a second example of the configuration of the optical path adjusting member 70.

The optical path adjusting member 70 includes a first refractive index member 72 and a second refractive index member 73.

The first refractive index member 72 has a lower refractive index than the second refractive index member 73. For example, the first refractive index member 72 is a silicon oxide layer and has a refractive index of about 1.45. Thus, the first refractive index member 72 has the same refractive index as the transmissive window 6d.

The second refractive index member 73 is a high-refractive-index member having a higher refractive index than the first refractive index member 72. For example, the second refractive index member 73 is a silicon nitride layer and has a refractive index of about 1.9.

The second refractive index member 73 has microlenses 731. The microlens 731 serving as a photorefractive member refracts light having passed through the transmissive window 6d, in the direction of light passing in the direction of the normal of the transmissive window 6d through the center of the transmissive window 6d. As illustrated in FIG. 15, the microlenses 731 are provided for each of the pixels 7. Moreover, the microlenses 731 are provided below the transmissive window 6d. In the example of FIG. 15, the microlens 731 has a convex portion protruding upward (toward the light emission side). For example, the microlens 731 is configured such that an optical axis OA at the center of the microlens 731 corresponds to a central point C of the transmissive window 6d. The first refractive index member 72 has recessed portions corresponding to the convex portions of the microlenses 731 on a contact surface with the second refractive index member 73.

Moreover, the bending angle of the optical path can be adjusted according to the design of the microlenses 731, for example, a curvature and the refractive index of the material of the second refractive index member 73. The refractive index of the second refractive index member 73 is adjusted by, for example, an addition agent as the refractive index of the optical control member 71.

The optical path adjusting member 70 is disposed on the opposite side of the first transparent substrate 31 from the display surface 2z of the first transparent substrate 31 on which the pixels 7 are disposed. Specifically, the optical path adjusting member 70 is disposed on the second surface F2 of the first transparent substrate 31. The first transparent substrate 31 has the first surface F1 on which the first self-emitting device 6a is provided and the second surface F2 on the opposite side of the first transparent substrate 31 from the first surface F1. In other words, the optical path adjusting member 70 is externally attached to the first transparent substrate 31. Thus, the optical path adjusting member 70 can be provided on the existing display panel 2 with relative ease. The optical path adjusting member 70 is, for example, a visible-light transmission film (microlens array film) that is bonded to the first transparent substrate 31 and has the microlenses 731.

Moreover, in plan view from the display surface 2z of the image display device 1, the optical path adjusting member 70 is disposed at least in a location overlapping the first pixel region 6 that is disposed directly above the sensor 5. In other words, the optical path adjusting member 70 does not need to be disposed in the second pixel region 8 that is not located directly above the sensor 5.

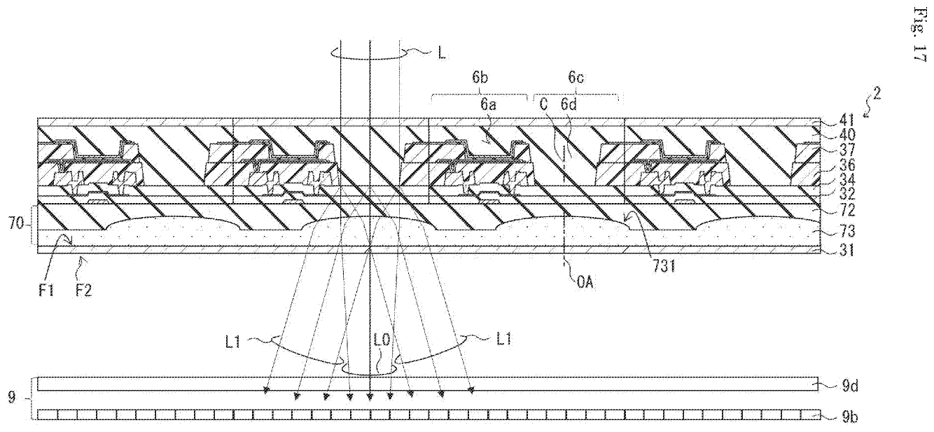

FIG. 17 is a cross-sectional view illustrating a third example of the configuration of the optical path adjusting member 70. The optical path adjusting member 70 in FIG. 17 is different from the optical path adjusting member 70 in FIG. 16 in that the positional relationship with the first transparent substrate 31 is reversed. Thus, the optical path adjusting member 70 is disposed on the display surface 2z of the first transparent substrate 31, on which the pixels 7 are disposed. Specifically, the optical path adjusting member 70 is disposed between the first surface F1 of the first transparent substrate 31 and the first self-emitting device 6a, the first transparent substrate 31 having the first surface F1 near the first self-emitting device 6a. In other words, the optical path adjusting member 70 is included in the display panel 2.

In the example of FIG. 17, the optical path adjusting member 70 is formed before the first self-emitting device 6a. The microlenses 731 (second refractive index member 73) can be formed by performing, for example, dry etching or wet etching multiple times on resist disposed on a transparent resin material with high transmittance of visible light. The first refractive index member 72 is then formed on the second refractive index member 73 to flatten the top surface of the first refractive index member 72. Thereafter, the first self-emitting device 6a is formed on the first refractive index member 72, so that the display panel 2 in FIG. 17 is completed.

If the optical path adjusting member 70 is included in the display panel 2 as illustrated in FIG. 17, the optical path adjusting member 70 may be disposed over the pixel region including both of the first pixel region 6 and the second pixel region 8. In this case, the microlenses 731 can be more evenly formed.

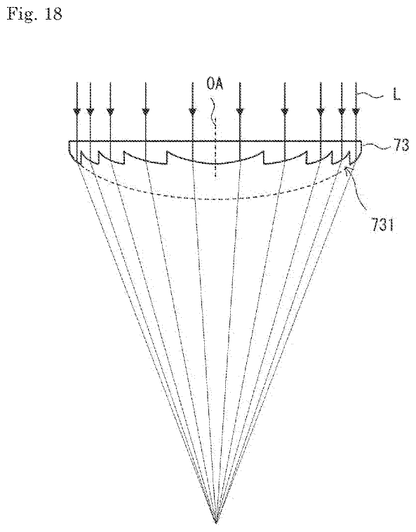

FIG. 18 illustrates a first modification example of the microlens 731. The microlens 731 is, for example, a Fresnel lens. A Fresnel lens is a lens formed by dividing a typical spherical lens (see a dotted line in FIG. 18) into substantially concentric regions with a smaller thickness. In other words, a Fresnel lens are serrated in cross section as illustrated in FIG. 18. Thus, the microlens 731 can be reduced in thickness, leading to a smaller thickness of the image display device 1 and the electronic device 50. Furthermore, a distance from the microlens 731 to the sensor 5 (image sensor module 9) can be shortened to suppress diffracted light f.

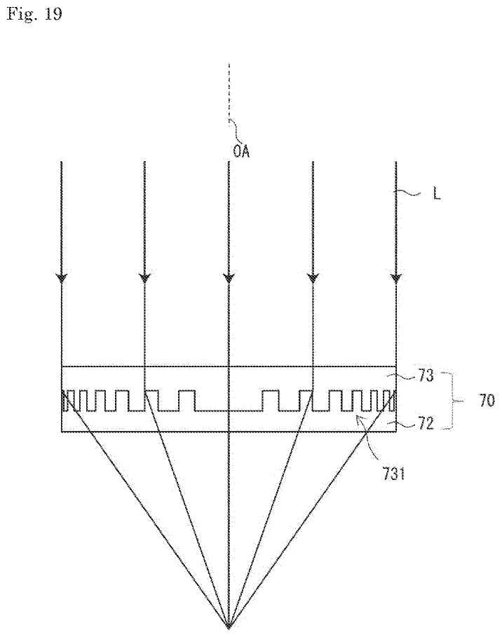

FIG. 19 illustrates a second modification example of the microlens 731. The microlens 731 is, for example, a diffractive lens. A diffractive lens is a lens that diffracts a light beam by using a diffraction phenomenon of light. Also in this case, the microlens 731 can be reduced in thickness like a Fresnel lens. Moreover, a diffractive lens can be fabricated with relative ease, facilitating manufacturing of the image display device 1 and the electronic device 50.

In some cases, the optical path adjusting member 70 bends the optical path of an object beam to be imaged, in addition to diffracted light. A change of the optical path of an object beam may cause image degradation, e.g., blurring of a capture image of the image sensor module 9. Thus, a method of suppressing the influence of image degradation by software image processing or the like may be used.

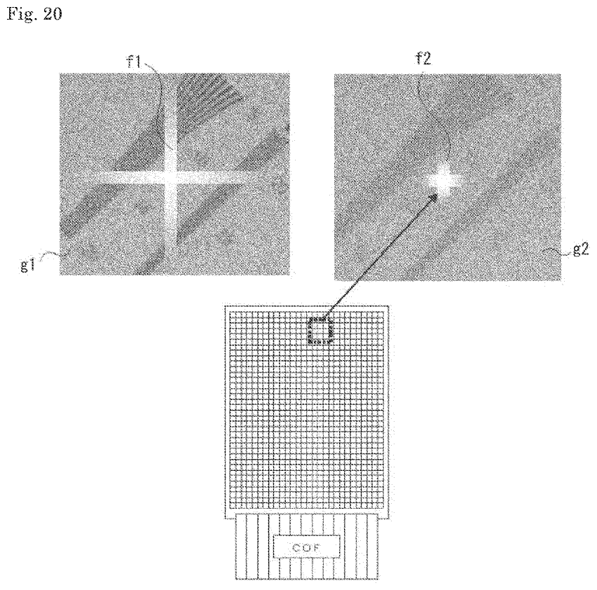

FIG. 20 illustrates a first example of suppression of image degradation. In FIG. 20, the image sensor module 9 is disposed immediately below the display panel 2. The optical path adjusting member 70 is disposed in the first pixel region 6 located directly above the image sensor module 9.

A captured image g1 indicates an image captured when light emitted from the transmissive window 6d is received by the image sensor module 9 without passing through the optical path adjusting member 70 as illustrated in FIG. 14 of the comparative example. A captured image g2 indicates an image captured when light emitted from the transmissive window 6d is received by the image sensor module 9 after passing through the optical path adjusting member 70 as illustrated in FIG. 15 of the present embodiment. In the example of FIG. 20, the captured image g1 is not obtained and only the captured image g2 is obtained.

As illustrated in FIG. 20, diffracted light f2 of the captured image g2 is smaller than diffracted light f1 of the captured image g1. The captured image g2 in a region other than the diffracted light f2 is more blurry than the captured image g1 in a region other than the diffracted light f1. In this case, for example, image processing using a deblurring filter or the like is performed on the captured image g2, thereby clarifying the captured image g2 in the region other than the diffracted light f2. The deblurring filter is, for example, edge enhancement. This can suppress the influence of the diffracted light f and the influence of image degradation by the optical path adjusting member 70.

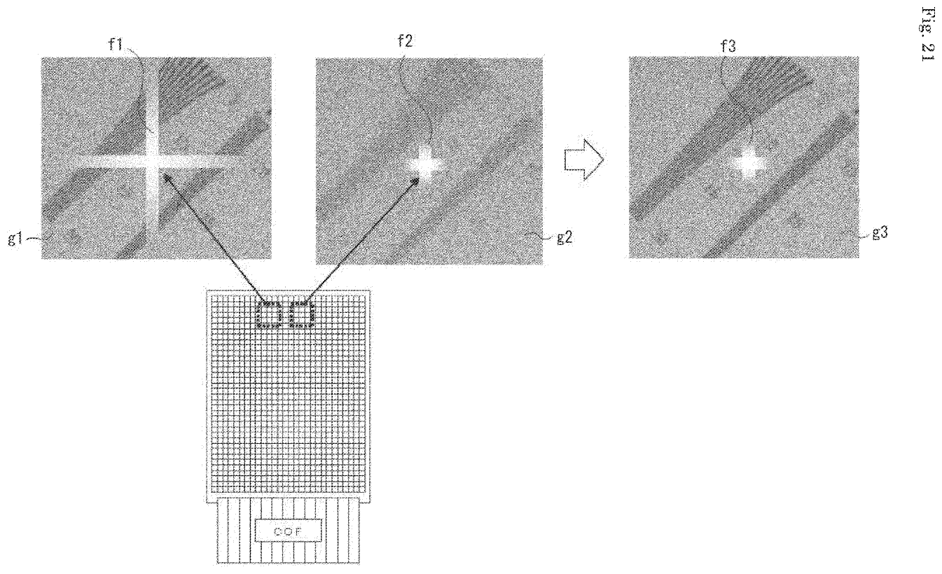

FIG. 21 illustrates a second example of suppression of image degradation. In FIG. 21, the two image sensor module 9 are disposed immediately below the display panel 2. The left optical path adjusting member 70 is not disposed in the first pixel region 6 located directly above the left image sensor module 9. The optical path adjusting member 70 is disposed in the first pixel region 6 located directly above the right image sensor module 9. Thus, the multiple transmissive windows 6d are provided. The transmissive windows 6d are disposed such that light having passed through some of the transmissive windows 6d enters the optical path adjusting member 70 and light having passed through the other transmissive windows 6d does not enter the optical path adjusting member 70. In other words, the optical path adjusting member 70 is disposed in a part of the first pixel region 6 such that light having passed through the transmissive windows 6d in the first pixel region 6 generates diffracted light with different sizes. Hence, FIG. 21 is different from FIG. 20 in that the captured image g1 is obtained in addition to the captured image g2.

A captured image g3 is a composite image of the captured image g1 and the captured image g2.

As illustrated in FIG. 21, the captured image g1 in a region other than the diffracted light f1 is a relatively clear image. Thus, in a region corresponding to the diffracted light f1, the synthesis of the captured image g3 by using the captured image g2 can suppress the influence of diffracted light. In other words, the region of the diffracted light f1 in the captured image g1 is augmented by the captured image g2 with suppressed diffracted light. This can suppress the influence of the diffracted light f and the influence of image degradation by the optical path adjusting member 70. Before being synthesized with the captured image g1, the captured image g2 may be subjected to image processing through a deblurring filter or the like. Thus, in the captured image g2, a region including diffracted light that is more suppressed than in the captured image g1 can be further clarified. This can further clarify the overall region other than diffracted light f3 as in the captured image g3.

As described above, in the present embodiment, the nonluminous region 6c is provided in the first pixel region 6 located directly above the sensor 5 disposed on the backside of the display panel 2, and the optical path adjusting member 70 is provided on the light emission side. With this configuration, light incident on the first pixel region 6 passes through the transmissive window 6d and enters the sensor 5. When the light passes through the transmissive window 6d, the diffracted light f is generated. The diffracted light f can be reduced by adjusting the optical path of the diffracted light, which is emitted through the transmissive window 6d, by means of the optical path adjusting member 70.

Moreover, image processing through a deblurring filter can suppress the influence of the diffracted light f and the influence of image degradation by the optical path adjusting member 70. Furthermore, by synthesizing the diffracted light f suppressed by the optical path adjusting member 70 and the diffracted light f having not passed through the optical path adjusting member 70, the influence of the diffracted light f and the influence of image degradation by the optical path adjusting member 70 can be suppressed.

A modification example of the structure of the transmissive window 6d will be described below.

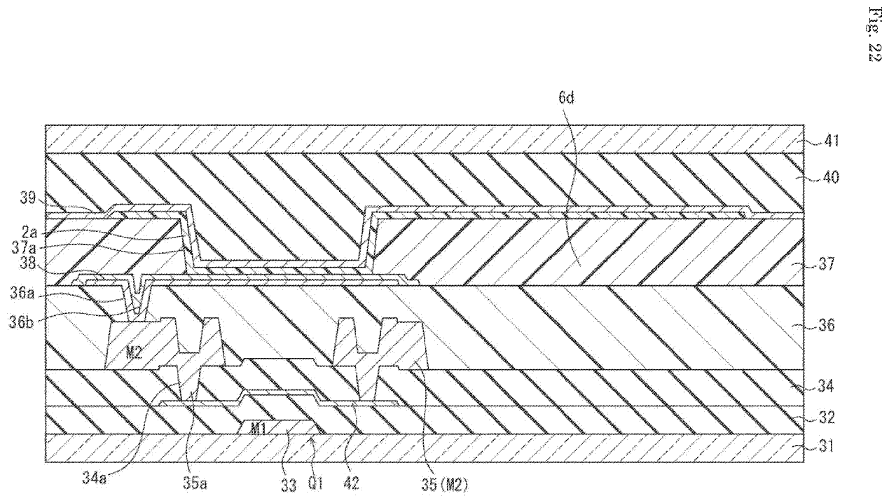

FIG. 22 is a cross-sectional view illustrating a first modification example of the cross-sectional structure of the first pixel region 6. FIG. 22 is different from FIG. 12 in that the third and fourth insulating layers 36 and 37, the display layer 2a, and the cathode electrode layer 39 are provided in the transmissive window 6d (a transmission region where light passes in the nonluminous region 6c). In the example of FIG. 22, the step for removing the third and fourth insulating layers 36 and 37, the display layer 2a, and the cathode electrode layer 39 can be omitted, facilitating manufacturing of the image display device 1 and the electronic device 50.

In the presence of the third and fourth insulating layers 36 and 37, the display layer 2a, and the cathode electrode layer 39, the transmittance of visible light may decrease. If the third and fourth insulating layers 36 and 37 are composed of colored resin layers, the transmittance of visible light may decrease. However, the presence of the third and fourth insulating layers 36 and 37 hardly affects the function of the transmissive window 6d. The display layer 2a has a small thickness of several hundred nm and thus hardly reduces the transmittance of visible light. The cathode electrode layer 39 is a transparent conductive layer. Even if the cathode electrode layer 39 has a laminated structure containing Ag, Ag has a small thickness as described above and thus hardly reduces the transmittance of visible light. Thus, a region where the anode electrode layer 38 acting as a reflective film has been removed acts as the transmissive window 6d in the presence of the third and fourth insulating layers 36 and 37, the display layer 2a, and the cathode electrode layer 39.

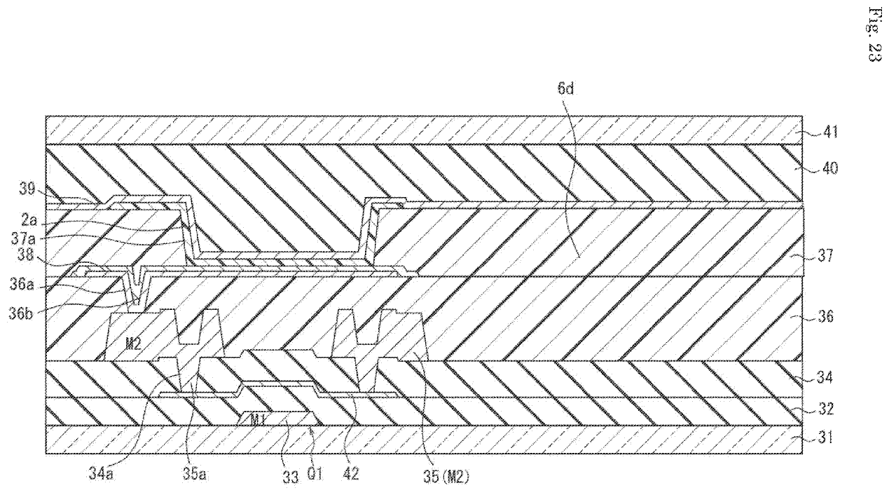

FIG. 23 is a cross-sectional view illustrating a second modification example of the cross-sectional structure of the first pixel region 6. FIG. 23 is different from FIG. 22 in that the display layer 2a is removed in the transmissive window 6d. Since the display layer 2a is not present in the transmissive window 6d, the absorption and reflection of light passing through the display layer 2a can be suppressed to increase the amount of light incident on the sensor 5, thereby increasing the light receiving sensitivity of the sensor 5.

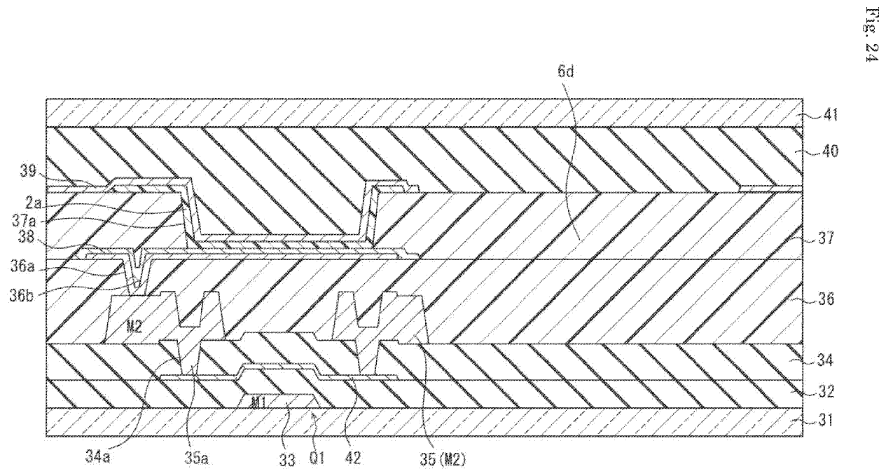

FIG. 24 is a cross-sectional view illustrating a third modification example of the cross-sectional structure of the first pixel region 6. FIG. 24 is different from FIG. 23 in that the cathode electrode layer 39 is removed in the transmissive window 6d. Since the display layer 2a and the cathode electrode layer 39 are not present in the transmissive window 6d, the amount of light incident on the sensor 5 can be larger than that of FIG. 23, so that the sensor 5 can have higher sensitivity to received light than in FIG. 23.

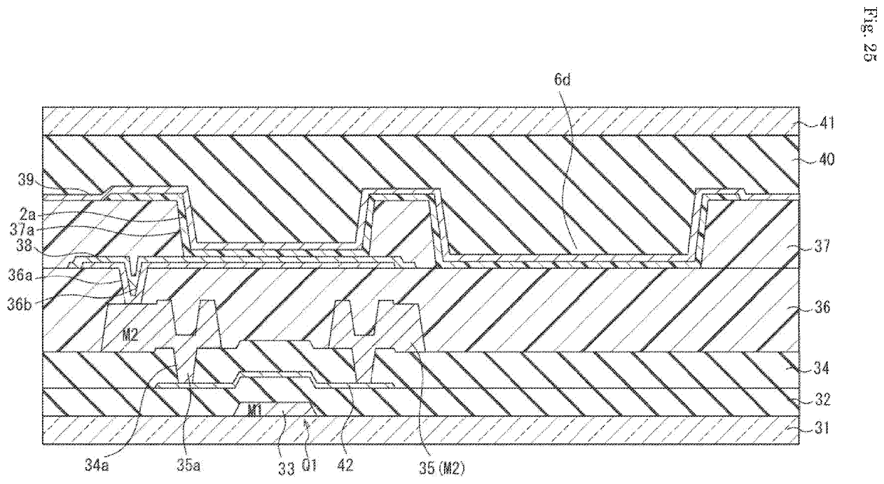

FIG. 25 is a cross-sectional view illustrating a fourth modification example of the cross-sectional structure of the first pixel region 6. FIG. 25 is different from FIG. 22 in that the fourth insulating layer 37 is removed in the transmissive window 6d. Since the fourth insulating layer 37 is not present in the transmissive window 6d, the absorption and reflection of light passing through the fourth insulating layer 37 can be suppressed to increase the amount of light incident on the sensor 5, thereby increasing the light receiving sensitivity of the sensor 5.

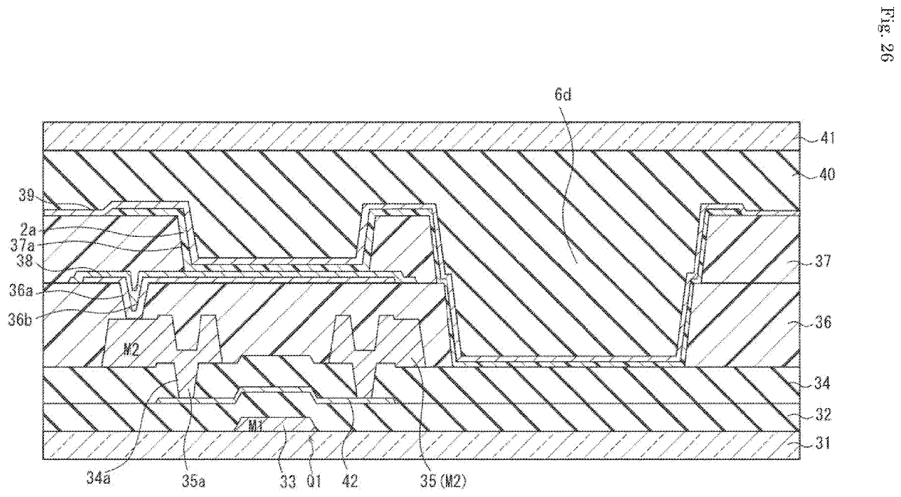

FIG. 26 is a cross-sectional view illustrating a fifth configuration example of the first pixel region 6. FIG. 26 is different from FIG. 25 in that the third insulating layer 36 is removed in the transmissive window 6d. Since the third and fourth insulating layers 36 and 37 are not present in the transmissive window 6d, the amount of light incident on the sensor 5 can be larger than that of FIG. 25, so that the sensor 5 can have higher sensitivity to received light than in FIG. 25.

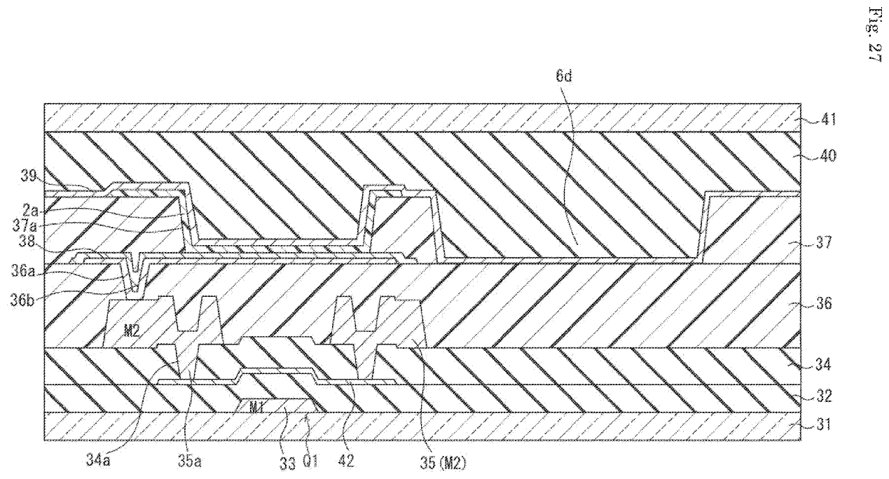

FIG. 27 is a cross-sectional view illustrating a sixth configuration example of the cross-sectional structure of the first pixel region 6. FIG. 27 is different from FIG. 25 in that the display layer 2a is removed in the transmissive window 6d. Since the fourth insulating layer 37 and the display layer 2a are not present in the transmissive window 6d, the amount of light incident on the sensor 5 can be larger than that of FIG. 25, so that the sensor 5 can have higher sensitivity to received light than in FIG. 25.

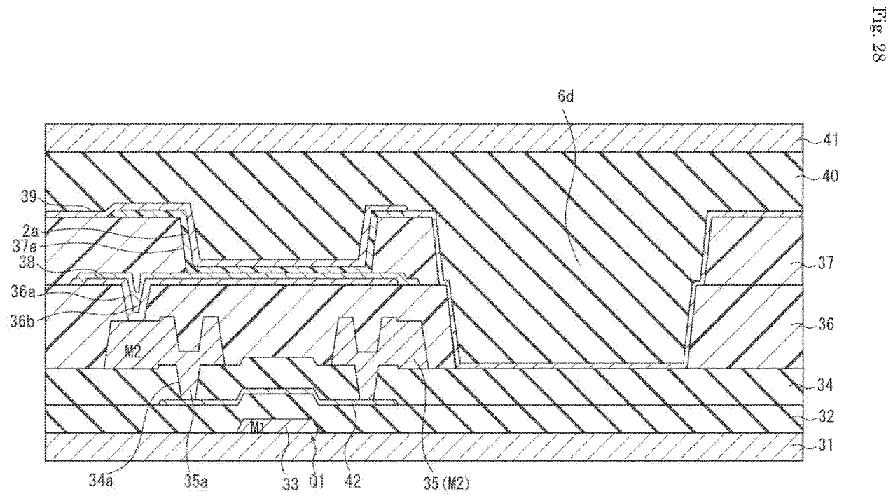

FIG. 28 is a cross-sectional view illustrating a seventh modification example of the cross-sectional structure of the first pixel region 6. FIG. 28 is different from FIG. 27 in that the third insulating layer 36 is removed in the transmissive window 6d. Since the third and fourth insulating layers 36 and 37 and the display layer 2a are not present in the transmissive window 6d, the amount of light incident on the sensor 5 can be larger than that of FIG. 27, so that the sensor 5 can have higher sensitivity to received light than in FIG. 27.

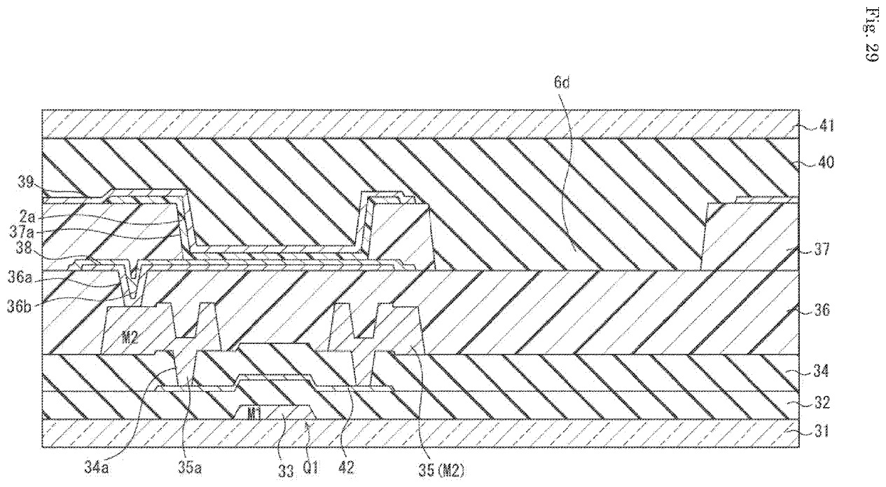

FIG. 29 is a cross-sectional view illustrating an eighth modification example of the cross-sectional structure of the first pixel region 6. FIG. 29 is different from FIG. 27 in that the cathode electrode layer 39 is removed in the transmissive window 6d. Since the fourth insulating layer 37, the display layer 2a, and the cathode electrode layer 39 are not present in the transmissive window 6d, the amount of light incident on the sensor 5 can be larger than that of FIG. 27, so that the sensor 5 can have higher sensitivity to received light than in FIG. 27.

The structure of the transmissive window 6d in FIG. 22 provides the greatest ease of manufacturing among FIGS. 22 to 29. The transmissive window 6d in FIG. 12 has a higher transmittance than the transmissive windows 6d in FIGS. 22 to 29. In this case, for example, a captured image in the image sensor module 9 can be illuminated. This can suppress an increase in noise as the sensitivity of the image sensor module 9 is improved. As described above, the structure of the transmissive window 6d may be changed according to a desired transmittance and the ease of the manufacturing process.

### Second Embodiment

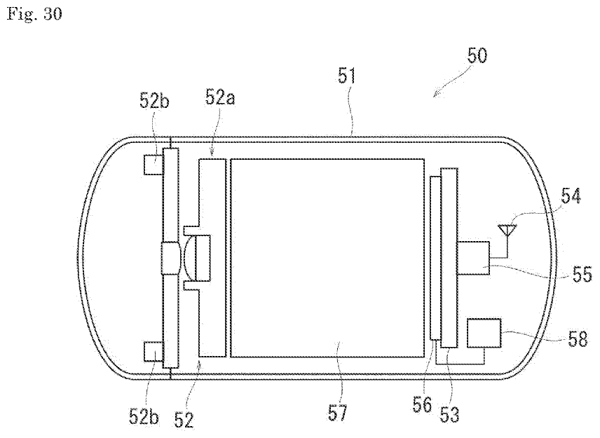

Various devices may be used as specific candidates of the electronic device 50 having the configuration described in the first embodiment. For example, FIG. 30 is a plan view of the electronic device 50 applied to a capsule endoscope according to the first embodiment. For example, the capsule endoscope 50 in FIG. 30 includes, in a cabinet 51 with both end faces hemispherical in shape and a central portion cylindrical in shape, a camera (subminiature camera) 52 for capturing an image in a body cavity, a memory 53 for recording image data acquired by the camera 52, and a radio transmitter 55 for transmitting the recorded image data to the outside via an antenna 54 after the capsule endoscope 50 is discharged out of the body of a subject.

In the cabinet 51, a CPU (Central Processing Unit) 56 and a coil (magnetic force/current converting coil) 57 are further provided. The CPU 56 controls imaging by the camera 52 and an operation for storing data in the memory 53 and controls data transmission from the memory 53 to a data receiver (not illustrated) outside the cabinet 51 by means of the radio transmitter 55. The coil 57 supplies power to the camera 52, the memory 53, the radio transmitter 55, the antenna 54, and light sources 52b, which will be described later.

The cabinet 51 further includes a magnetic (reed) switch 58 for detecting the setting of the capsule endoscope 50 into the data receiver. The CPU 56 supplies power from the coil 57 to the radio transmitter 55 when the reed switch 58 detects the setting into the data receiver and data transmission is enabled.

The camera 52 includes, for example, an imaging element 52a including an object optical system for capturing an image in a body cavity and the light sources 52b for illumination in the body cavity. Specifically, the camera 52 includes, for example, a CMOS (Complementary Metal Oxide Semiconductor) sensor including an LED (Light Emitting Diode) or a CCD (Charge Coupled Device) as the light source 52b.

A display part 3 in the electronic device 50 according to the first embodiment is a concept including emitters such as the light sources 52b in FIG. 30. For example, the capsule endoscope 50 of FIG. 30 includes the two light sources 52b. The light sources 52b can be configured as a display panel having a plurality of light source units or an LED module having a plurality of LEDs. In this case, the imaging unit of the camera 52 is disposed below the display panel or the LED module so as to reduce constraints to the layout of the camera 52, thereby downsizing the capsule endoscope 50.

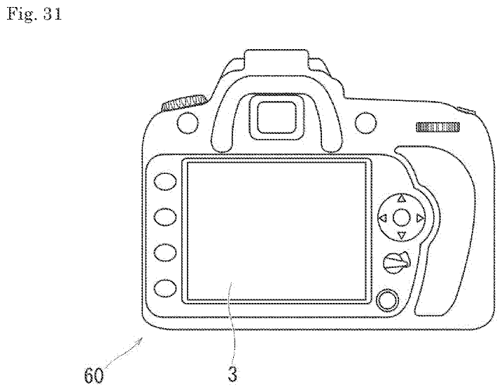

FIG. 31 is a rear view of the electronic device 50 applied to a digital single-lens reflex camera 60 according to the first embodiment. The digital single-lens reflex camera 60 and a compact camera are provided with the display part 3 for displaying a preview screen on the back of the camera, that is, on the opposite side of the camera from a lens. Camera modules 4 and 5 may be disposed on the opposite side of the camera from the display surface of the display part 3 so as to display a face image of a photographer on the display layer 2a of the display part 3. In the electronic device 50 according to the first embodiment, the camera modules 4 and 5 can be disposed in a region overlapping the display part 3. This can eliminate the need for providing the camera modules 4 and 5 at the bezel of the display part 3, thereby maximizing the size of the display part 3.

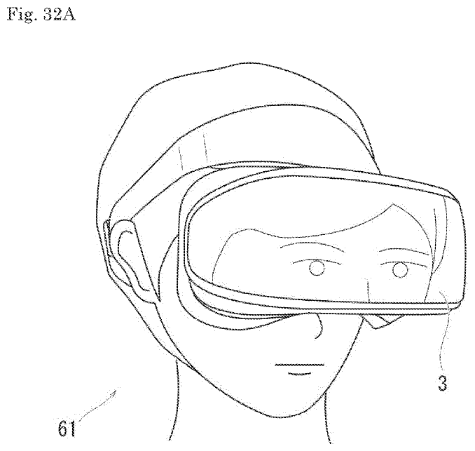

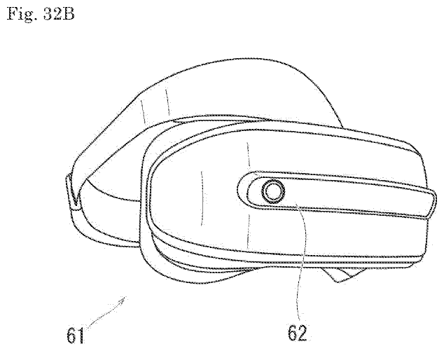

FIG. 32A is a plan view illustrating an example of the electronic device 50 applied to a head-mounted display (hereinafter referred to as an HMD) 61 according to the first embodiment. The HMD 61 in FIG. 32A is used for, for example, VR (Virtual Reality), AR (Augmented Reality), MR (Mixed Reality), or SR (Substitutional Reality). As illustrated in FIG. 32B, the existing HMD has a camera 62 on the outer surface. A person wearing the HMD can visually recognize an image of a surrounding area but unfortunately, persons around the wearer of the HMD cannot recognize the eyes and facial expressions of the wearer.

For this reason, in FIG. 32A, the display surface of the display part 3 is provided on the outer surface of the HMD 61 and the camera modules 4 and 5 are provided on the opposite side of the HMD 61 from the display surface of the display part 3. Thus, the facial expressions of the wearer imaged by the camera modules 4 and 5 can be displayed on the display surface of the display part 3, allowing persons around the wearer to recognize the facial expressions and eye movements of the wearer in real time.

In the case of FIG. 32A, the camera modules 4 and 5 are provided on the backside of the display part 3. This eliminates constraints to the location of the camera modules 4 and 5, thereby increasing flexibility in the design of the HMD 61. Furthermore, the camera can be disposed at the optimum position, thereby preventing problems such as a deviation of a wearer's line of vision on the display surface.

As described above, in the second embodiment, the electronic device 50 according to the first embodiment can be used for a variety of uses, thereby improving the usefulness.

The present technique can be configured as follows:

(1) An image display device including a plurality of pixels that are two-dimensionally arranged,

wherein each of at least some of the plurality of pixels includes:

a first self-emitting device;

a first luminous region illuminated by the first self-emitting device;

a nonluminous region having a transmissive window that allows passage of visible light; and

an optical path adjusting member that is disposed on a light emission side opposed to the light entry side of the transmissive window and adjusts the optical path of light having passed through the transmissive window.

(2) The image display device according to (1), wherein the optical path adjusting member adjusts the optical path of light having passed through the transmissive window, so that the optical path of light gets closer to the direction of light passing in the direction of the normal of the transmissive window through the center of the transmissive window.

(3) The image display device according to (1) or (2), wherein the optical path adjusting member adjusts the optical path of diffracted light of light having passed through the transmissive window.

(4) The image display device according to any one of (1) to (3), wherein, in plan view from the display surface side of the image display device, the nonluminous region is disposed at a position overlapping a light receiving device for receiving light passing through the image display device.

(5) The image display device according to any one of (1) to (4), wherein a pixel circuit connected to the first self-emitting device is disposed in the first luminous region.

(6) The image display device according to any one of (1) to (5), wherein the optical path adjusting member includes a photorefractive member that refracts light having passed through the transmissive window, in the direction of light passing in the direction of the normal of the transmissive window through the center of the transmissive window.

(7) The image display device according to (6), wherein the optical path adjusting member is disposed on the opposite side of a substrate from the display surface of the substrate on which the plurality of pixels are disposed.

(8) The image display device according to (7), wherein the optical path adjusting member is a visible-light transmission film that is bonded to the substrate and has the photorefractive member.

(9) The image display device according to (6), wherein the optical path adjusting member is disposed on the display surface side of a substrate on which the plurality of pixels are disposed.

(10) The image display device according to any one of (6) to (9), wherein the photorefractive member is a Fresnel lens or a diffractive lens.

(11) The image display device according to any one of (1) to (5), wherein the optical path adjusting member includes an optical control member having a higher refractive index than the material of the transmissive window.

(12) The image display device according to (11), wherein the optical control member contains an addition agent that raises the refractive index of the optical control member higher than the refractive index of the transmissive window.

(13) The image display device according to (11) or (12), wherein the optical control member is disposed in a location where light travels after passing through the transmissive window in a substrate on which the plurality of pixels are disposed.

(14) The image display device according to any one of (1) to (13), further including first pixel regions including some of the plurality of pixels; and second pixel regions including at least some of the plurality of pixels other than the pixels in the first pixel regions,

wherein the pixel in the first pixel region may include the first self-emitting device, the first luminous region, and the nonluminous region, and

the pixel in the second pixel region may include:

a second self-emitting device; and

a second luminous region that is illuminated by the second self-emitting device

and has a larger area than the first luminous region.

(15) The image display device according to (14), wherein the first pixel regions are spaced at a plurality of points in a pixel display region.

(16) The image display device according to (14) or (15), wherein, in plan view from the display surface side of the image display device, the optical path adjusting member is disposed at least in a location overlapping the first pixel region.

(17) The image display device according to (14) or (15), wherein the plurality of transmissive windows are provided, and

the plurality of transmissive windows are disposed such that light having passed through some of the transmissive windows enters the optical path adjusting member and light having passed through the other transmissive windows does not enter the optical path adjusting member.

(18) An electronic device including: an image display device including a plurality of pixels that are two-dimensionally arranged; and

a light receiver that receives light passing through the image display device,

wherein the image display device has first pixel regions including some of the plurality of pixels,

each of said some of the pixels in the first pixel regions includes:

a first self-emitting device;

a first luminous region illuminated by the first self-emitting device;

a nonluminous region having a transmissive window that allows passage of visible light; and

an optical path adjusting member that is disposed on a light emission side opposed to the light entry side of the transmissive window and adjusts the optical path of light having passed through the transmissive window, and

in plan view from the display surface side of the image display device, at least some of the first pixel regions are disposed so as to overlap the light receiver.

(19) The electronic device according to (18), wherein the light receiver receives light through the nonluminous region.

(20) The electronic device according to (19), wherein the light receiver includes at least one of an imaging sensor that performs photoelectric conversion on incident light passing through the nonluminous region, a distance measuring sensor that receives incident light passing through the nonluminous region and measures a distance, and a temperature sensor that measures a temperature on the basis of incident light passing through the nonluminous region.

Aspects of the present disclosure are not limited to the aforementioned individual embodiments and include various modifications that those skilled in the art can achieve, and the effects of the present disclosure are also not limited to the details described above. In other words, various additions, modifications, and partial deletion can be made without departing from the conceptual idea and the gist of the present disclosure that can be derived from the details defined in the claims and the equivalents thereof.

### REFERENCE SIGNS LIST

1 Image display device

2 Display panel

2a Display layer

5 Sensor

6 First pixel region

6a First self-emitting device

6b First luminous region

6c Nonluminous region

6d Transmissive window

7 Pixel

8 Second pixel region

8a Second self-emitting device

8b Second luminous region

9 Image sensor module

9a Support substrate

9b Image sensor

9c Cutoff filter

9d Lens unit

9e Coil

9f Magnet

9g Spring

10 Subject

11 Specific pixel

12 Pixel circuit

12a Anode electrode

31 First transparent substrate

32 First insulating layer

33 First wiring layer

34 Second insulating layer

35 Second wiring layer

36 Third insulating layer

36a Trench

37 Fourth insulating layer

38 Anode electrode layer

39 Cathode electrode layer

40 Fifth insulating layer

41 Second transparent substrate

42 Semiconductor layer

43 Capacitor

44 Metallic layer

45 Third metallic layer

70 Optical path adjusting member

71 Optical control member

731 Microlens

1. An image display device comprising a plurality of pixels in a two-dimensional array,
wherein each of at least some of the plurality of pixels includes:
a first self-emitting device;
a first luminous region illuminated by the first self-emitting device;
a nonluminous region having a transmissive window that allows passage of visible light; and
an optical path adjusting member that is disposed on a light emission side opposed to a light entry side of the transmissive window and adjusts an optical path of light having passed through the transmissive window.

2. The image display device according to claim 1, wherein the optical path adjusting member adjusts the optical path of light having passed through the transmissive window, so that the optical path of light gets closer to a direction of light passing in a direction of a normal of the transmissive window through a center of the transmissive window.

3. The image display device according to claim 1, wherein the optical path adjusting member adjusts an optical path of diffracted light of light having passed through the transmissive window.

4. The image display device according to claim 1, wherein, in plan view from a display surface side of the image display device, the nonluminous region is disposed at a position overlapping a light receiving device for receiving light passing through the image display device.

5. The image display device according to claim 1, wherein a pixel circuit connected to the first self-emitting device is disposed in the first luminous region.

6. The image display device according to claim 1, wherein the optical path adjusting member includes a photorefractive member that refracts light having passed through the transmissive window, in a direction of light passing in a direction of a normal of the transmissive window through a center of the transmissive window.

7. The image display device according to claim 6, wherein the optical path adjusting member is disposed on an opposite side of a substrate from a display surface of the substrate on which the plurality of pixels are disposed.

8. The image display device according to claim 7, wherein the optical path adjusting member is a visible-light transmission film that is bonded to the substrate and has the photorefractive member.

9. The image display device according to claim 6, wherein the optical path adjusting member is disposed on a display surface side of a substrate on which the plurality of pixels are disposed.

10. The image display device according to claim 6, wherein the photorefractive member is a Fresnel lens or a diffractive lens.

11. The image display device according to claim 1, wherein the optical path adjusting member includes an optical control member having a higher refractive index than a material of the transmissive window.

12. The image display device according to claim 11, wherein the optical control member contains an addition agent that raises a refractive index of the optical control member higher than a refractive index of the transmissive window.

13. The image display device according to claim 11, wherein the optical control member is disposed in a location where light travels after passing through the transmissive window in a substrate on which the plurality of pixels are disposed.

14. The image display device according to claim 1, further comprising: first pixel regions including some of the plurality of pixels; and
second pixel regions including at least some of the plurality of pixels other than the pixels in the first pixel regions,
wherein the pixel in the first pixel region includes the first self-emitting device,
the first luminous region, and the nonluminous region, and
the pixel in the second pixel region includes:
a second self-emitting device; and
a second luminous region that is illuminated by the second self-emitting device and has a larger area than the first luminous region.

15. The image display device according to claim 14, wherein the first pixel regions are spaced at a plurality of points in a pixel display region.

16. The image display device according to claim 14, wherein, in plan view from a display surface side of the image display device, the optical path adjusting member is disposed at least in a location overlapping the first pixel region.

17. The image display device according to claim 14, wherein the plurality of transmissive windows are provided, and the plurality of transmissive windows are disposed such that light having passed through some of the transmissive windows enters the optical path adjusting member and light having passed through the other transmissive windows does not enter the optical path adjusting member.

18. An electronic device comprising: an image display device including a plurality of pixels that are two-dimensionally arranged; and
a light receiver that receives light passing through the image display device, wherein the image display device has first pixel regions including some of the plurality of pixels,
each of said some of the pixels in the first pixel regions includes:
a first self-emitting device;
a first luminous region illuminated by the first self-emitting device;
a nonluminous region having a transmissive window that allows passage of visible light; and
an optical path adjusting member that is disposed on a light emission side opposed to a light entry side of the transmissive window and adjusts an optical path of light having passed through the transmissive window, and
in plan view from a display surface side of the image display device, at least some of the first pixel regions are disposed so as to overlap the light receiver.

19. The electronic device according to claim 18, wherein the light receiver receives light through the nonluminous region.

20. The electronic device according to claim 19, wherein the light receiver includes at least one of an imaging sensor that performs photoelectric conversion on incident light passing through the nonluminous region, a distance measuring sensor that receives incident light passing through the nonluminous region and measures a distance, and a temperature sensor that measures a temperature on a basis of incident light passing through the nonluminous region.
